(19) United States
(12) Patent Application Publication
(10) Pub. No.: US 2002/0061662 A1
(43) Pub. Date: May 23, 2002

(54) Fabrication and application of nano-manipulators with induced growth

(76) Inventor: Peter Boggild, Copenhagen (DK)

Correspondence Address: BIRCH STEWART KOLASCH & BIRCH, PO BOX 747, FALLS CHURCH, VA, 22040-0747, US

(21) Appl. No.: 09/938,153

(22) Filed: Aug. 24, 2001

Related U.S. Application Data
(60) Provisional application No. 60/227,592, filed on Aug. 25, 2000.

(51) Int. Cl. H01L 21/00

(52) U.S. Cl. 438/800

(57) ABSTRACT

The present invention relates to fabrication and application of nano-manipulators with induced growth using a focused particle beam. Induced growth may be used to fabricate nano-manipulators, such as a nano-tweezers or grippers, which allows for a very precise and flexible design. Also, applying the growth techniques together with nano-manipulators provides a strong tool for performing complex operations performing pick & place operations with nanoscale structures and fabrication of other nano-manipulators.

### FIELD OF THE INVENTION

The present invention relates to fabrication and application of nano-manipulators with induced growth using a focused particle beam. Induced growth may be used to fabricate nano-manipulators, such as a nano-tweezers or grippers, which allows for a very precise and flexible design. Also, applying the growth techniques together with nano-manipulators provides a strong tool for performing complex operations performing pick & place operations with nanoscale structures and fabrication of other nano-manipulators.

### BACKGROUND OF THE INVENTION

Nanotechnology is a rapidly evolving technology and the technology for studying microand nanoscale structures by the use of for example AFM and STM is well established. The technology is now evolving towards not only studying or imaging atomic-scale surfaces and objects, but also measuring and manipulating individual atoms and molecules.

Scanning Probe Microscopes including the AFMs and STMs have proven to be powerful tools for manipulating atoms and molecules. The nanomanipulation, however being basically limited to pushing nanostructures into desired positions on a surface with the microscope tip or stretching nanostructures between the microscope tip and the surface. The single probe tip used in these devices limits the ability to manipulate the objects and measure the physical properties since one tip cannot grab an object and most electrical measurements on a nanoscale cannot be made with only a single probe.

Micrometer-scale electromechanical tweezers capable of manipulating micrometer-scale structures, have been fabricated in silicon, cf. for example U.S. Pat. No. 5,149,673, MacDonald et al., disclosing micro-mechanical tweezers having two tungsten cantilever beams forming the tweezers. The tweezers may move in three dimensions by the application of potential differences between the beams and between the beams and the silicon substrate, respectively. For example, tweezers of length 200 μm and having a cross-section of 2.7×2.5 μm will close upon application of a voltage of approximately 150 V. The potential difference between the tungsten cantilevers produces an attractive electrostatic force that can overcome the elastic restoring force of the beams whereby the tweezers are closed

Considering the size of the cantilever beams, only micrometer-scale objects may be manipulated.

Pushing towards grabbing individual nanostructures, moving the nanostructures freely in three dimensions, and furthermore measure the physical properties of the nanostructures, such as atoms, molecules and small particles, requires the development of new techniques and new tools.

An example of such a new tool is the nanotube nanotweezers disclosed by Philip Kim and Charles M. Lieber (Science, 286, 2148-2150). The device comprises a glass needle with two carbon nanotubes (a 2 nm thin hollow wire made entirely out of carbon atoms) attached to the needle, the distance between the nanotubes being 2 μm. Electrical connections are formed so that a voltage may be applied between the two carbon nanotubes. According to the applied voltage the carbon nanotubes will bend closer to each other from their relaxed positions and eventually close (at an applied voltage of 8.5V). Once an object has been grabbed by the nanotweezers the electrical properties of the object may be probed by using the nanotube arms as conducting wires. By, for example, measuring the current through the nanostructure the conductivity of the nanostructure may be measured.

Kim et al. (Journal of Micromechanical Systems, Jan. 31, 1992 and Technical Digest. IEEE Solid-State Sensor and Actuator Workshop (Cat. No. 90CH2783-9)) discloses a microgripper which is electrostatically driven by flexible, interdigitated comb pairs. The tip elements are fabricated by deposition, photolithography, and etching.

Kakushima et al (MEMS 2001, 14th International Conference on Micro Electro Mechanical Systems, Interlake, Switzerland) discloses a microgripper with thermally activated gripping function. The tip elements are fabricated by deposition, photolithography, and etching.

Many of the nanoscale structures to be manipulated are fragile and the voltage difference applied between the electrodes may damage fragile nanostructures, such as cells and biomolecules. Another limitation is the shape of the tip elements, the parts which actually grabs the nanoscale structures to be manipulated. Often the size, shape and material composition of the tip elements are determined by the method of fabrication and method of actuation, and can thereby not be designed to fit a given application.

### SUMMARY OF THE INVENTION

It is an object of the present invention to provide a single manipulator for manipulating, e.g. grabbing, moving, measuring and imaging nanoscale structures.

It is another object of the present invention to provide a nano-manipulator capable of manipulating nanoscale structures without applying any other than mechanical forces to the objects to be manipulated.

It is a further object of the present invention to provide a nano-manipulator capable of manipulating nanoscale structures of various shapes and compositions in that the size, shape and material composition of the tip elements can be designed to fit the structure to be manipulated.

It is a still further object of the present invention to provide a method for fabricating nano-manipulators according to the previous objects.

It is a still further object of the present invention to provide a method for performing pick & place operations with nanoscale structures by positioning a nanoscale structure in relation to another object and attaching the nanoscale structure to the object.

It is a still further object of the present invention to provide another method for fabricating further nano-manipulators using a nano-manipulator according to the previous objects.

According to a first aspect, the present invention provides a nano-manipulator comprising

a first and a second beam anchored to a support in at least one point,

first and second manipulator means held by the first and second beam respectively, said manipulator means being formed by induced growth with a focused particle beam,

the first and/or the second beam being flexible between at least a first and a second relative position, wherein a distance between the first and second manipulator means in the first and the second position are different, and

means for applying an actuation force to the first and/or the second beam for moving the first and/or the second beam between the first and the second position.

According to a second aspect, the present invention provides a method for fabricating a nano-manipulator, the method comprising the steps of:

providing a support,

forming a first and a second beam anchored to the support in at least one point,

placing the first and second beams at low pressure and in the presence of materials to be grown,

forming a first manipulator means by directing a focused particle beam to the first beam to induce growth of the first manipulator means and controlling the thickness, length, and shape of the first manipulator means by controlling one or more predetermined parameters of the particle beam and/or beam moving the particle beam focus in relation to the first beam in a predetermined way,

forming a second manipulator means by directing a focused particle beam to the second beam to induce growth of the second manipulator means and controlling the thickness, length, and shape of the second manipulator means by controlling one or more predetermined parameters of the particle beam and/or moving the particle beam focus in relation to the second beam in a predetermined way,

wherein the materials to be grown at least partly determine the material composition of the first and second manipulator means, wherein the first and/or the second beam are/is flexible between at least a first and a second relative position, and wherein a distance between the first and second manipulator means in the first and the second position are different, and

providing means, held by the nano-manipulator, for moving the first and/or the second beam between at least the first and the second position.

Preferably, the means for moving the first and/or the second beam comprises means for applying an actuation force to the first and/or the second beam for moving the first and/or the second beam between the first and the second position.

In the following, a number of details related to the various aspects of the invention will be discussed, some in relation to preferred embodiments.

The manipulator means may comprise tip elements, such as elongated tip elements, needles, etc., and the manipulator means may be conductive, non-conductive, or semiconductive.

The manipulator means, hereafter also denoted tip elements, may be fabricated by inducing growth using a focused particle beam. The tip elements may for example be fabricated by the tip fabrication method disclosed in WO 00/03252. Specifically, the tip elements may be carbon containing manipulator means fabricated by the electron beam deposition technique disclosed in WO 00103252. Hereby, the tip elements may be deposited at the respective beam so that one tip element is deposited at the beam, while the second tip element is deposited at the free end of the first tip element, either pointed in the same direction as the first tip element, or pointed at a non-zero angle with respect to the direction of the first tip element. A similarly applicable technique, which are well known by the person skilled in the art, are described and investigated in Matsui et al., J. Vac. Sci. Technol. B 18(6), p 3181, 2000 and references therein.

The technique of induced growth using a focused particle beam will be briefly described below, please refer to one or more of the following references for a more throughout description; High-Resolution Electron Beam Induced Deposition, Koops H. W. P., Weiel R., Kern D. P., Baum TH., Journal of Vacuum Science & Technology B, 6, 477-481, 1988 or Focused Ion-Beam Technology and Applications, Melngalis J. Journal of Vacuum Science & Technology B, 5, 469-495, 1987.

With the present techniques for growing nanoscale structures using induced growth by particle beams, the method of fabrication can be determined by various microscopy methods and can thus be distinguished from structures fabricated by deposition, photolithography, and etching.

The induced growth using a focused particle beam is typically explained by ionisation or dissociation (activation) of the atoms/molecules in a growth chamber (vacuum chamber) by the particle beam in its focus region which generates free radicals in this region. Free radicals are typically very reactive and will bind to each other and any nearby substance, such as the beam on which one wants to grow upon, much similar to the crystallisation in a super-saturated solution. Whether the activated atoms/molecules is induced to grow on or deposited on the beam is only a question of terminology, and both terms will be used in the present description. The particle beams thus primarily serves to prepare or activate the atoms/molecules and does not as such contribute to the grown material (although this might also be the case for some particle beams). The particle beam may therefore be any beam capable of ionising or dissociating the atoms/molecules, e.g. electron beam ion beam, laser beam etc. The atoms/molecules to be grown (or equivalently the material to be grown) may be free atoms/molecules in the growth chamber such as contamination or background “gasses”(typically too dilute to behave like a gas) or they may be injected to the growth region from a nozzle. Alternatively, the material to be grown may be deposited on the target so that it evaporates or sublimates when hit by the particle beam, thereby generating free atoms/molecules to be grown. Also, it follows that it is primarily the composition of the material to be grown that determines the material composition of the grown material. By adjusting the composition of the material to be grown, one may determine the material properties of the grown material, e.g. thermal/electrical conductivity, dielectric properties, magnetic properties, crystal structure, strength, flexibility, weight, etc.

The free radicals will usually bind to the nearest suitable position. By moving the focus of the particle beam, the region with free radicals will also move, and due to their limited lifetime and mobility, so will their binding position. Thereby, the direction of the growth can be controlled simply by moving the particle beam focus. In short and simple terms, moving the focus faster will make the grown structures thinner whereas moving the focus slower will make the grown structures thicker. The direction and properties of the growth may also be controlled without moving the beam and focus, but by controlling other parameters of the particle beam, e.g. the time of growth.

The properties of the growth and the grown materials depends on numerous parameters. For example, changing the size and strength of the focus or the density of the background atmosphere may generate fewer or more free radicals and may be used to control the dimensions of the grown structure as well as the speed of growth. Other parameters of the particle beam for controlling the growth are beam current (charged particles), beam flux (neutral particles), acceleration voltage, beam intensity, beam size and shape, beam particles, beam angle of incidence on target, growth time. Also, the material to be grown may be varied, as well as its density or distribution, e.g. by having nozzles in the growth chamber for directing material to be grown to the region where the particle beam meets the target.

The manipulator means may be tip element(s) having predetermined length(s), the length of the individual tip element being measured along the tip element from the end secured to the beam electrode to the freely moving end, the length of several consecutive tip elements being measured as the sum of the lengths of the individual tip elements. The length of the elongated tip elements may be between 50 nm and 100 μm, such as between 100 nm and 100 μm, such as between 100 nm and 10 μm, for example such as between 500 nm and 10 μm, such as between 500 nm and 5 μm. The elongated tip element may, further, define a diameter, the diameter being between 10 nm and 10 μm.

The electric properties of the tip elements may be modified by introducing contaminants in the growth chamber during deposition of the tip elements. Alternatively, the tip elements may be coated afterwards. For example, a non-conductive tip element may be coated by a conductive coating. The conductive coating may for example be evaporated on the tip element, such as by sputtering or electron beam deposition. By tilting the tip element during evaporation so that two or more application angles are used, a suitable metallic coating of the tip elements may be obtained. Furthermore, a coating may be applied to reduce friction and/or adhesion between the manipulator means and the objects to be manipulated, this may for example be obtained by coating the tip elements by a Teflon® coating or any other material capable of reducing the friction and/or adhesion. In general, the dielectric properties of the coating should be matched to the objects and the environment in which the manipulator means performs.

Further, the means for applying an actuation force preferably comprises

a plurality of actuator beams anchored to the support in at least one point, the plurality of actuator beams being adapted to apply an actuation force to the first and second beams, and

a control circuit for controlling actuation forces applied by the plurality of actuator beams to the first and second beams.

Also, the actuation beams are preferably adapted to apply a force to the first and second beams, the force being chosen from the group comprising electrostatic forces, piezoeresistive forces, piezoelectric forces, ferroelectric forces, ferromagnetic forces, thermoelectric forces, electromagnetic forces, etc.

Thus, preferably, the manipulator means are moved in response to the applied actuation force without applying any actuation force to or between the manipulator means. Hereby, the nanostructures to be manipulated are not affected by the applied actuation force fields, so that the fragile nanostructures are not damaged by the applied actuation force fields.

The beams may be adapted to respond to the actuation force applied and, hence, the beams may comprise a material being responsive to the respective actuation force to be applied. When, for example, the force to be applied is an electrostatic force, the beams may be silicon dioxide cantilever beams covered with a thin conductive film. The conductive film may be made of any conducting material, such as Au, Ag, Pt, Ni, Ta, Ti, C, Cr, Cu, Os, W, Mo, Ir, Pd, Cd, Re, conductive diamond, conductive polymers, metal silicides or any combinations thereof. Alternatively, the beams may be fabricated of any of the above-mentioned metals, or the beams may be fabricated in any semiconducting material, part of the material being doped to improve the conductive properties of the semiconducting material. Furthermore, the beams may be fabricated using silicon-oninsulator substrates, where the top silicon layer may be doped so that the conductive properties of the top silicon layer is improved, the cantilever beams may comprise the intermediate insulator part, and the silicon substrate may be etched away to free the cantilever beams.

The support may comprise any material, such as ceramic or semiconducting materials, such as Ge, Si or combinations thereof. Use of the semi-conducting materials allows for standard microfabrication technology to be used for the manufacturing of the suspended beams, but also other fabrication methods may be used for manufacturing of the beams. Furthermore, the beams may be mounted on the support after manufacturing of the beams.

The part of the principal surface over which the first and second pluralities of beams are suspended may be the anchor point, or the first and second pluralities of beams may be partly or fully suspended over the principal surface of the support.

In one embodiment of the invention the first and second beams may be substantially parallel to the actuation beams. Each of the beams of the first and the actuation beams may have a length and a width, the ratio between the length and the width being between 500:1 and 5:1, such as for example 50:1, preferably such as 10:1.

The length and the width of the beams may be chosen so that the elastic properties of the beams are suitable for the specific application. Furthermore, the length of each of the beams of the first and second beams may be larger than the length of each of the beams of the actuation beams, such as to provide for separation between the fields generated when the actuation beams applies an actuation force to the first and second beams and the manipulator means.

For example, when applying an electrostatic actuation force to the first and second beams, the electric fields should not interfere with the manipulator means. If the electric fields interfere with the manipulator means, electrostatic charge may build up at the manipulator means resulting in, for example, repellent forces between the manipulation means at each of the plurality of beams in the first and second beams, irrespective of the forces applied to the first and second beams.

To further remove the fields generated by the actuation beams from the manipulator means, the actuation force may be applied indirectly, i.e. the actuation force from the actuation beams may be transmitted through any force transmitting elements, such as gears, springs, etc.

In another preferred embodiment at least part of at least one of the actuation beams and/or at least part of at least one of the first and second beams may define a comb actuator.

The comb actuator structure may for example have 2-50 interdigitating fingers, each finger may have a length being between 1 μm and 10 μm. The distance between the interdigititing fingers may be between 0.1 μm and 5 μm. However, it is to be understood that the comb actuator may be defined so that optimum transmission of actuation forces are obtained.

The first and second beams may comprise at least two beams and up to 64 beams, i.e. at least a first and a second beam electrode, each comprising manipulator means. Hereby, the two manipulator means may be adapted to manipulate, e.g. move, grab, grasp, pinch, pull, bend, push, assemble, connect, break, manipulate, measure, image, sense, etc, any object positioned in contact with at least one manipulator means. The manipulator means positioned at each of the at least two beams of the first and second beams thus functioning basically as tweezers, such as tongs, nippers, pinches, pliers, etc., the tweezers also being capable of imaging, measuring, sensing, etc when the appropriate connections are made to the manipulator means.

The nanostructures to be manipulated may be any small particles, atoms, molecules, bio molecules, DNA, wires, threads, nanotubes, cells, such as nerve cells etc. and the nanostructures may be of any form such as spherical, elliptical, cubic, rectangular, triangular, polyhedral, amorphous, etc.

The objects to be manipulated may have a cross-section between 1 nm and 10 μm and may furthermore have a length up to 1 mm, such as a length between 1 nm and 1 mm, such as between 5 nm and 1 mm.

The actuation beams may comprise one, two, three, four or up to 64 beams. In a preferred embodiment two beams may be positioned at either side of the first plurality of the beams and none or at least one beam electrode may be positioned between the at least two beams of the first and second beams. By having at least one beam electrode between the at least two beams of the first and second beams both closing and opening operations of the tweezers may be performed. It is envisaged that many arrangements of the beams may be obtained. For example, a range of tweezers positioned parallel or tweezers having more than two arms for specific applications, e.g. designed to grab objects of a specific form, may be manufactured.

The gap between the two manipulator means may be between 1 nm and 20 μm, such as between 1 nm and 500 nm, such as between 5 and 100 nm, such as between 1 and 50 nm, such as between 5 and 20 nm, preferably the gap is substantially equal to or below 100 nm, such as equal to or below 50 nm, or equal to or below 20 nm, or equal to or below 10 nm, or equal to or below 5 nm, or equal to or below 1 nm.

The nano-manipulator may be designed so that actuation forces applied to the first and second beams may induce a movement of the manipulator means corresponding to full or partly closing of the manipulator means, for example by application of a moderate to low voltage to the actuation beams, the moderate to low voltage being dependent of the design of the nano-manipulator, but the low voltage being for example at or below 5 V, such as below 1 V, such as 0.1 V, and the moderate voltage being for example more than 5V, such as more than 10 V, such as more 20 V or more than 30 V.

In a preferred embodiment, at least one of the beams of the actuation beams is positioned between the first and the second beam electrode of the first and second beams, for example in a centre position. Hereby, not only opening of the tweezers by pulling the first and second beams apart from each other by applying an actuation force to the outer beams, but also closing of the tweezers by applying an actuation force to the centre beam electrode may be accomplished. Applying an actuation force on at least one beam electrode positioned between the first and the second beam electrode of the first and second beams, the centre electrode, decreases the distance between the first and the second beam electrode of the first and second beams, hence closing the tweezers at least partly.

Using one of the above-mentioned fabrication methods, the manipulator means may be manufactured in any appropriate form so that the manipulator means may be adapted to manipulate objects of any form, such as any form chosen from the group comprising spherical, elliptical, cubic, rectangular, triangular, polyhedral, amorphous, etc. forms.

In a preferred embodiment, the manipulator means may be electrically connected to a control circuit, so that the control circuit may be adapted to control electrical measurements being performed by the manipulator means.

Furthermore, the nano-manipulator may comprise positioning means for positioning the manipulator in three dimensions, with respect to a surface or an object to be manipulated. The positioning means being for example an adjustable XYZ table or a piezoelectric micro/nano-manipulator.

The nano-manipulator may further comprise interface means for controlling the operation of the nano-manipulator. The nano-manipulator may for example be controlled via a computer and the interface means may comprise any keyboards, computer mouse, joysticks, track pads, data gloves, computer input devices, digitisers, digitiser pens, etc., or any combination thereof.

Still further, the nano-manipulator may comprise scanning means and/or imaging means for scanning the manipulator means over a surface part of an object and/or for creating an image of a surface part of the object. This may be the sample being moved with the manipulator being fixed or the manipulator being moved with the sample being fixed. The imaging may be performed by position feedback using/measuring interactions between the manipulator means, acting as an atomic force manipulator, and the surface part of the object (AFM mode), or alternatively the scanning and imaging may be performed by position feedback using/measuring tunnelling current between the manipulator means and the surface part of the object (STM mode).

Furthermore, the nano-manipulator may also be used in other modes of operation, such as any scanning probe microscopy mode, such as in force modulation mode, lateral force microscopy mode, scanning thermal microscopy mode, scanning capacitance mode, phase imaging mode, etc.

According to the present invention, the induced growth using a focused particle beam may also be applied to form joints between two or more objects so as to mechanically connect the objects and thereby attach them to each other. According to this application, the induced growth can be considered as welding or soldering the objects together. The induced growth can join two separated objects to form a mechanical connection or can secure two abutting objects by growing material on or around the point of contact.

According to a third, fourth and fifth aspect of the present invention, the application of the induced growth for attaching and modifying objects, hereafter also denoted as welding, is exploited.

According to the third aspect, the present invention provides a method for performing pick & place operations with nanoscale objects, the method comprising the steps of

providing a member and a nanoscale object to be attached to the member,

providing a nano-manipulator adapted to grip and hold nanoscale objects, the nanomanipulator being movable in relation to the member,

gripping and holding the object with the nano-manipulator,

positioning the object close to or in contact with the member by moving the nanomanipulator holding the nanoscale object,

attaching the object to the member, and

releasing the nano-manipulator's grip on the object.

Preferably, the step of attaching the object to the member comprises the step of inducing material growth joining the object and the member by directing a focused particle beam to a region on the member/object and moving the particle beam focus towards the object/member to join the member and the object by the grown material.

The nanoscale object may be translated and/or rotated in relation to the member by holding the nanoscale object with the nano-manipulator and translating and rotating the nano-manipulator in relation to the member. The nano-manipulator may be a nano-manipulator according to the first aspect, such as a nano-manipulator fabricated according to the second aspect.

The nanoscale object may be previously grown using a focused particle beam whereby it would be possible to control the size, shape, and material composition of the object. Alternatively, the object may be a carbon nanotube, a silicon nanowire or any type of semiconducting nanowires, metallic nanowires, or insulating nanowires.

According to a fourth and a fifth aspect, the present invention provide two further method for fabricating nano-manipulators, both based on the welding of nanoscale objects to a larger member using a focused particle beam. As compared to the method for fabricating according to the second aspect, the fourth and fifth aspect simply provides methods where it is not the whole manipulating means which are grown using induced growth. Instead, at least part of the manipulating means, or tip elements, are prefabricated (possibly by induced growth) and attached to the beams using induced growth. The tip elements may be further modified by induced growth after attachment to the beams.

According to the fourth aspect, the present invention provides a method for fabricating a second nano-manipulator using a first nano-manipulator, the method comprising the steps of:

providing a support,

forming a first and a second beam anchored to the support in at least one point,

providing a first and a second nanoscale tip element

placing the first and second beams and the first and second tip elements at low pressure and in the presence of materials to be grown,

providing a first nano-manipulator adapted to grip and hold nanoscale objects, the nano-manipulator being movable in relation to the first and second beams,

attaching the first tip element to the first member by

gripping and holding the first tip element with the first nano-manipulator,

positioning the first tip element close to or in contact with the first beam by moving the first nano-manipulator holding the tip element,

inducing material growth joining the first tip element and the first beam by directing a focused particle beam to an anchorage point on the first beam or the first tip element, and

releasing the grip of the first tip element by the first nano-manipulator,

attaching the second tip element to the second member by

gripping and holding the second tip element with the first nano-manipulator,

positioning the second tip element close to or in contact with the second beam by moving the first nano-manipulator holding the tip element,

inducing material growth joining the second tip element and the second beam by directing a focused particle beam to an anchorage point on the second beam or the second tip element, and

releasing the grip of the second tip element by the first nano-manipulator,

wherein the first and/or the second beam are/is flexible between at least a first and a second relative position, and wherein a distance between the first and second tip elements in the first and the second position are different, and

providing means, held by the second nano-manipulator, for moving the first and/or the second beam between at least the first and the second position.

The fabricated second nano-manipulators according to the fourth aspect may be used as first nano-manipulators to fabricate more nano-manipulators. Also, some of the fabricated second nano-manipulators may be used as electrode points in an SEM scheme for providing an electron beam to be used as the focused particle beam whereas others may prepare, cut into pieces and sort the tip elements to be attached. Thereby, a small “factory” for reproduction of nano-manipulators may be envisaged.

The first nano-manipulator may be a nano-manipulator according to the first aspect.

According to the fifth aspect, the present invention provides a method for fabricating a nano-manipulator, the method comprising the steps of:

providing a support,

forming a first and a second beam anchored to the support in at least one point,

providing a first and a second nanoscale tip element

placing the first and second beams and the first and second tip elements at low pressure and in the presence of materials to be grown,

positioning the first tip element close to or in contact with the first beam,

inducing material growth joining the first tip element and the first beam by directing a focused particle beam to an anchorage point on the first beam or the first tip element,

positioning the second tip element and the second beam close to, or in contact with, each other,

inducing material growth joining the second tip element and the second beam by directing a focused particle beam to an anchorage point on the second beam or the of second tip element,

wherein the first and/or the second beam are/is flexible between at least a first and a second relative position, and wherein a distance between the first and second tip elements in the first and the second position are different, and

providing means, held by the second nano-manipulator, for moving the first and/or the second beam between at least the first and the second position.

The step of inducing material growth joining a tip element and a beam may comprise moving the particle beam focus from the beam/tip element towards the tip element/beam to join the beam and the tip element together by the grown material.

In a preferred embodiment, at least one of the tip elements is a carbon nanotube, a silicon nanowire or any type of semiconducting nanowires, metallic nanowires, or insulating nanowires. In another preferred embodiment, the tip elements are formed by induced growth in a controlled atmosphere using a focused particle beam.

Preferably, the means for moving the first and/or the second beam comprises means for applying an actuation force to the first and/or the second beam for moving the first and/or the second beam between the first and the second position. The actuation force may be chosen from the group comprising electrostatic forces, piezoeresistive forces, piezoelectric forces, ferroelectric forces, ferromagnetic forces, thermoelectric forces, electromagnetic forces, etc.

### BRIEF DESCRIPTION OF THE DRAWINGS

FIG. 1 shows an overview of the nano-manipulator with electrical connections,

FIG. 2 shows a schematic nano-manipulator and the distance between the manipulator means,

FIG. 3 shows a nano-manipulator structure having substantially parallel beams,

FIG. 4 shows a nano-manipulator structure having comb actuator beams,

FIGS. 5A-C show the actuation principle for a nano-manipulator having one, two and three beam electrode(s), respectively, in the actuation beams,

FIGS. 6A-C show different applications of the nano-manipulator, and

FIGS. 7A-L show the stepwise fabrication method for the tip elements.

FIGS. 8A-B and 9A-B illustrates pick & place operation of a nanoscale object according to the present invention using a nano-manipulator.

FIG. 10 illustrates a method according to the present invention for fabricating a second nano-manipulator using a first nano-manipulator.

FIGS. 11A and B illustrates another method according to the present invention for fabricating of a nano-manipulator.

### DETAILED DESCRIPTION OF THE PREFERRED EMBODIMENTS

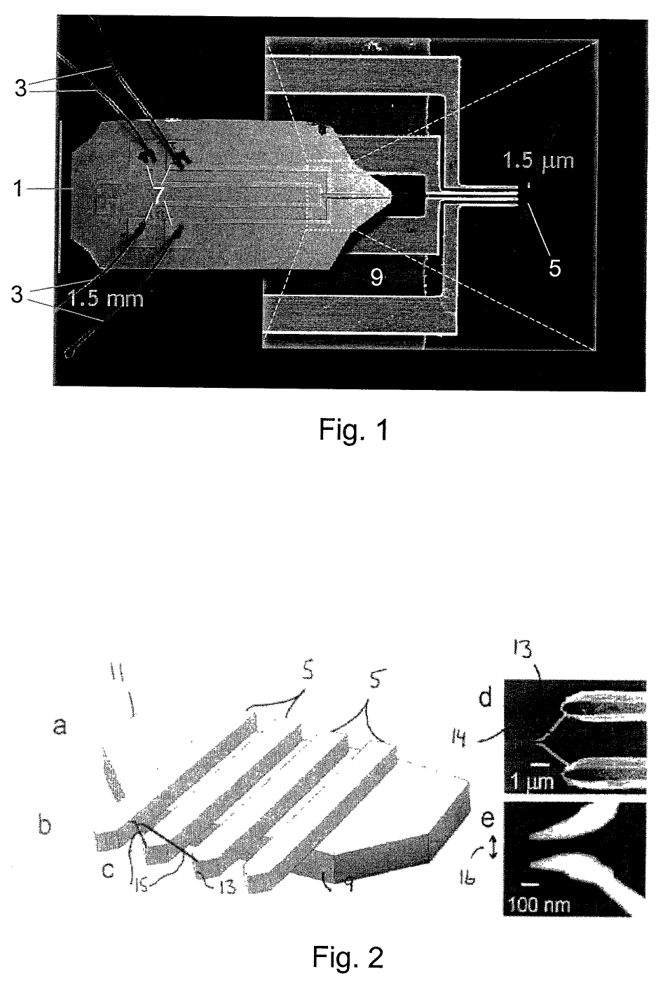

In FIG. 1 the basic microprobe is shown. The electrode region 1 is magnified so that the suspended beams 5 may be seen. In FIG. 1, four beams 5 are shown, the beams in one end being suspended over the support 1. The beams are widened in the other end so as to form contact pads 7, so that the device may be wire-bonded and thereby electrically connected via bonding wires 3 to external electronics, such as control circuits, etc. (not shown).

The four beams 5 are fabricated of silicon oxide and the microfingers are suspended over the edge 9 of the silicon support 1. The size of the support is 3×1.5 mm. The distance between the centre axis of two neighbouring suspended beams is between 0.5 and 60 microns. To make the device conducting the surface is covered with a thin metallic layer anisotropically from the top. Due to the undercutting of the silicon oxide layer, the conductive layer on each microfinger is separated from the other electrodes as well as the conductive layer on the silicon support 1.

In FIG. 2a a schematic nano-manipulator structure is shown. A silicon microchip 11 supports the four beams 5 and the edge 9 of the silicon support is also shown. At the ends 13 of two of the beams, manipulator means 15 are deposited. The tip elements 15 are 100 nm wide and 0.1-60 microns long. FIG. 2b shows an enlarged view of the tip elements 13 and it is seen that the free end of the tip element 14 is twisted so as to form an angle relative to the other part of the tip element. In FIG. 2c it is seen that the gap 16 is tuned to 100 nm.

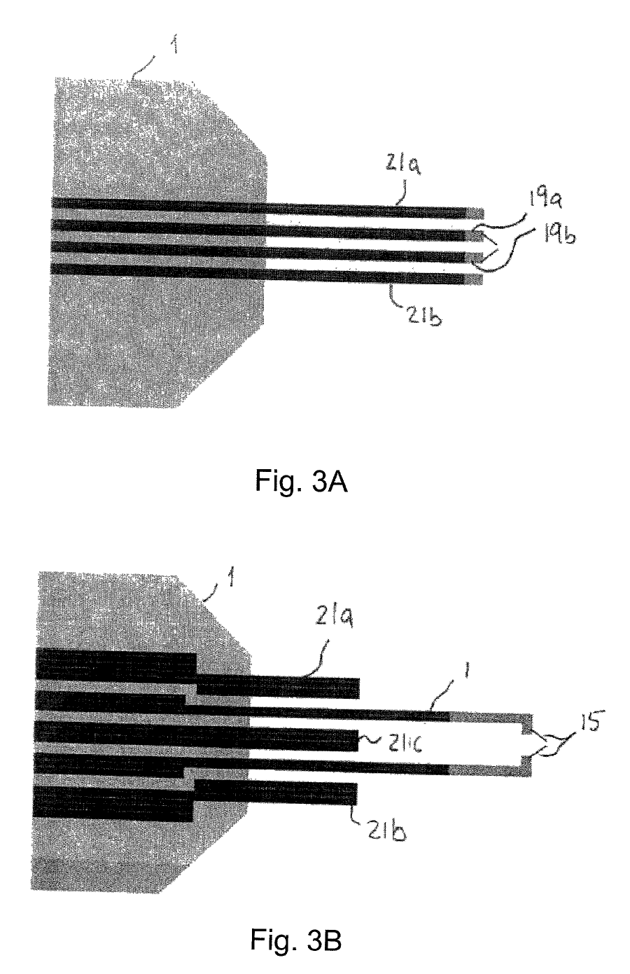

FIGS. 3a shows a nano-manipulator structure having substantially parallel beams, a first plurality of beams 19a, 19b are provided with manipulator means 15. The actuation beams 21a, 21b are adapted to apply an electrostatic force to the first and second beams 19. It is seen that the outermost part of the beams 21 are not coated by a conductive film so that no force fields, for example no electrical fields are generated close to the manipulator means 15.

In FIG. 3b the actuation beams 21a-c are drawn back so that also the electrical fields are drawn further back from the manipulator means, and so that a central beam electrode provide closing actuation in addition to the opening actuation.

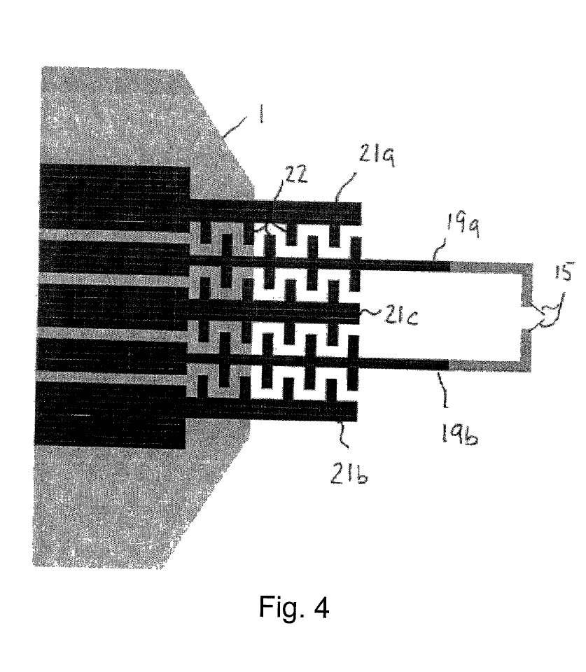

FIG. 4 shows another configuration of the beams. The beams having a comb structure so that the first and second beams 19 are interdigitating with the actuation beams 21. As it is seen only part of the beams form a comb structure. Due to the comb structure the actuation force is transferred more efficient than if the first and second beams and the actuation beams were substantially parallel. Hereby, a larger movement of the first and second beams, and, hence, of the manipulator means, may be obtained by a lower actuation voltage.

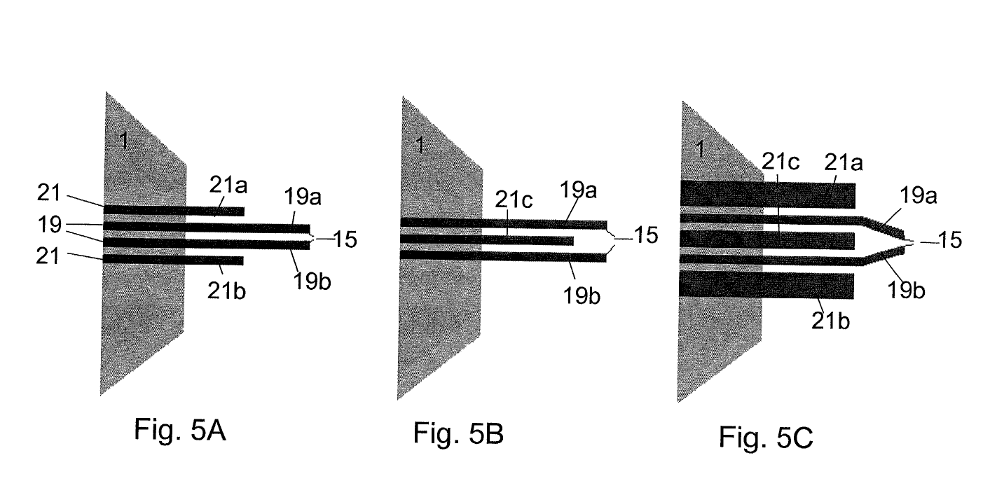

FIGS. 5a-c show the actuation principle for a nano-manipulator having two, one and three beam electrode(s), respectively, in the actuation beams.

In FIG. 5A the driver electrodes 21a, 21b are able to move the manipulator means 15 further apart, i.e. open the tweezers. By applying an actuation voltage to the driver electrodes 21a, 21b positioned at the outer side of the active electrodes 19a, 19b, and having 0 V at the active electrodes, the driver electrode 21a will pull the active electrode 19a towards the driver electrode 21a and correspondingly, the driver electrode 21b will pull the active electrode 19a towards the driver electrode 21a. Thus, the active electrodes are moved away from each other.

In FIG. 5B the driver electrode 21c is positioned between the active electrodes 19a,19b so that the active electrodes upon application of an actuation voltage to the driver electrode 21c will be attracted to the driver electrode 21c, thus the manipulator means will be moved towards each other and thereby closing the tweezers, fully or partly.

In FIG. 5C the three driver electrodes 21a-c are assembled in a single device, so that both closing and opening actuation is obtained.

The manipulator means 15 may be fabricated so that they may close fully upon application of an actuation voltage to the driver electrodes, or, alternatively, the manipulator means 15 may only close partly. If no actuation voltage is applied to either the driver electrodes 21 or the active electrodes 19 no actuation forces will act between the beams, and, hence, the manipulator means will be in a released position. Applying actuation forces to the active beam electrodes 19 does only deform the beams elastically so that they may return to the released position when the actuation forces are removed.

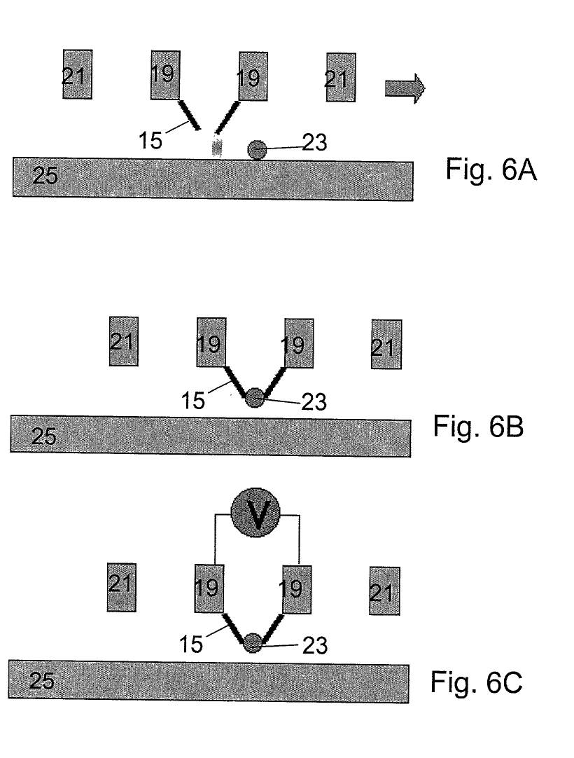

FIGS. 6a-c show different operation schemes for the nano-manipulator. In FIG. 6a, the nano-manipulator operates in a scanning probe microscopic mode where the tip element is probing the surface 25 and by measuring for example the tunnelling current as in an STM, an image of the surface 25 is obtained.

FIG. 6b shows the nano-manipulator operating in tweezers/grabber mode, so that objects or particles 23 may be grabbed and/or moved.

In FIG. 6c, the nano-manipulator measures electric properties of the object 23 by applying a voltage between the active electrodes 19a, 19b, the voltage being sufficiently small not to damage the object 23.

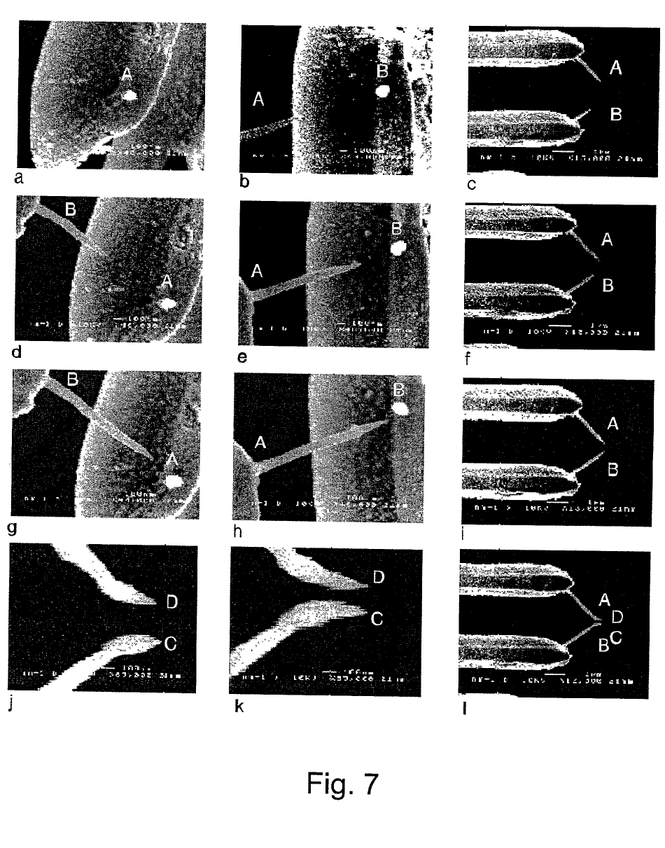

FIGS. 7A-L show the stepwise fabrication method for the tip elements. Using beaminduced deposition, two narrow supertips are deposited in converging directions. The supertips are typically 50-150 nm wide, may be several microns long, and may be shaped to fit the application. The fabrication scheme described below allow converging supertips to be deposited in plane, and with full control over the resulting gap, as well as the shape of the tip elements or nanofingers 15. By depositing parallel (as opposed to tilted) tips at the ends of the tilted tips, the length and the gap can be fine-tuned to within 10 nm or less. In the preferred process tilt and rotation of the sample is combined in a way so that it is ensured that the tip elements are in-plane, symmetric and with an adjustable gap.

FIG. 7A shows the view during deposition of tip element A, with the image viewing angle parallel to the tip element and perpendicular to the surface, FIG. 7B shows the view during deposition of tip element B and FIG. 7C shows an overview in a 45 degree angle with respect to the beams, but approximately perpendicular to the plane of the tip elements. FIG. 7D-I are similar to FIGS. 7A-C and shows the ongoing deposition process. In FIG. 7J two tip elements C, D are grown at the free ends of tip elements A and B. The tips are grown in the forward direction, however still tilted with respect to the beams. In FIG. 7K the resulting tips are shown to be of equal length and with a 100 nm gap. This may be obtained be carefully timing the deposition and by moving the deposition beam towards the centre of the gap between the tip elements C and D during growth, also a reduction in the gap is seen. In FIG. 7I a final overview of the tip elements shows the angled tip elements A and B with the parallel supertips at the ends. Each final tip element thus being composed of the tip elements A and D and the tip elements B and C, respectively.

Alternatively, the gap can be tuned to within less than 10 nm during scanning, as opposed to the method of depositing parallel tip elements. As in the parallel tip element method, the starting point is such as shown in FIG. 7I, with converging tip elements separated by a gap of 50-200 nm. By adjusting the tilt and rotation of the support structure to obtain a frontal view of the electrodes, and adjusting the scan field to a sufficiently small area, the deposition of carbon material proceeds at a considerable rate, even during scanning of the electron beam, i.e. viewing. Within seconds to minutes, depending on the deposition conditions, the gap is seen to decrease. When the gap has reached a sufficiently small size, the magnification is reduced in order to terminate the deposition at the ends of the tip elements.

By using this or similar three-dimensional deposition techniques, it is envisaged that any three-dimensional manipulator means may be grown. The induced growth does not have to be done with the focused beam parallel to the growth direction (such as described in relation to FIG. 7A), the focused beam might as well be perpendicular to the growth direction, or any other angle, which then requires the focused beam to move (translate and/or rotate) during deposition, “lateral” growth.

Nanowelding of one carbon nanotube to another has recently been done (Banhart, F, NanoLetters, 1, 329-332, 2001)—however none of the welded tubes were held in place in any way—they are accidentally close enough to be weld together.

The present invention consider the situation that a nanotweezers holds the wire close to for instance an electrode or a cantilever—where you want it to sit—and then spot-weld/glue the wire onto the object using the focused particle beam, i.e. a beam equivalent to the one described previously used to fabricate manipulator means.

The third aspect proposes a method of attaching a nanoscale object, such as for instance a wire or a tube, to a target member using a nano-manipulator in a pick & place operation. The attachment procedure using the focused particle beam may be described as welding, soldering, attaching, connecting or gluing. The nano-manipulator is mounted on a device capable of moving the nano-manipulator in all three directions, inside a scanning beam microscope. The nanoscale object to be attached is either free-standing, free-hanging, suspended between two objects, or lying on a surface. The location on the target member where the nanoscale object is attached is termed the target area.

In order to perform pick & place operations, the nano-manipulator should both grip and release of the object, i.e. close and open the tweezers. A nano-manipulator which can close and open is described in relation to FIGS. 5A-C. Thus, closing according to FIG. 5A can be obtained by decreasing the voltage between the active and the outer driver beams, whereas closing according to FIG. 5B can be obtained by increasing the voltage between the active beams and the inner driver beam. A manipulator according to FIG. 5C can be closed by either of these two methods or by a combination.

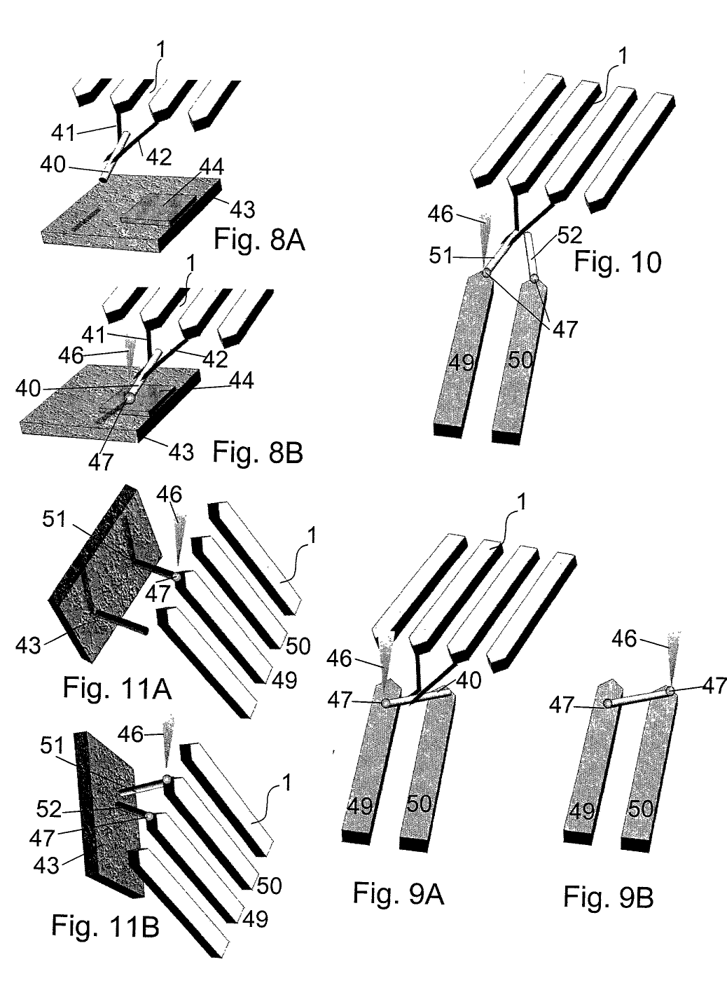

The pick & place operation starts with a grip and hold operation as illustrated in FIG. 8A. showing a nanoscale object 40 being held by a nano-manipulator 1 with tip elements 41 and 42. If the diameter of the nanoscale object 40 exceeds the gap of the nano-manipulator 1, the gap between the tip elements 41 and 42 is opened until the gap size is larger than the diameter of the nanoscale object 40. The nano-manipulator 1 is then moved, so that the nanoscale object 40 is located between the tip elements. The nano-manipulator 1 is then closed using one the methods described above, until the nanoscale object 40 is held/locked mechanically between the tip elements 41 and 42. If necessary, force is applied to the nanoscale object 40 in order to detach or release it from its present position.

As illustrated in FIG. 8B, the nanoscale object 40 is now being moved until one end is within 100 nm of a target area 44, which may be a surface or another object 43. The focus of a beam 46 of a scanning beam microscope is now focused on the target area. The beam interacts with material, such as molecules, near the target area until an amount of material is deposited on the target object 43, in such a way that the nanoscale object 40 is mechanically and maybe electronically connected to the target area 44 of the target object 43. The beam is illustrated as a triangle in FIG. 8B, and the deposit material connecting the nanoscale object 40 and the object 43, is shown as a sphere 47 at the lower corner of the triangle.

As another example illustrated in FIG. 9A and B, the nano-manipulator can be used to attach an nanoscale object between the two active beams of another manipulator or any other pair of electrodes, beam, platforms, objects, cantilevers, holders etc. In FIG. 9A, the nano-manipulator 1 is holding a nanoscale object 40 while it is being attached to a first beam 49. The object 40 can be positioned by the nano-manipulator 1 so that both ends are close enough to the beams 49 and 50 to make attachment possible, or the object 40 can be bend towards the second beam 50, after being fixed to the first 49. In FIG. 4b, the other end of the elongated object is attached to a second beam.

According to the method of the fourth aspect, a first, existing nano-manipulator can be applied to fabricate a second, “target” nano-manipulator. As illustrated in FIG. 10, a tip element 51 is moved by a nano-manipulator 1 so that one end is in within approximately 100 nm of a target beam 49, of an unfinished nano-manipulator. The focused particle beam 46 beam is then used to attach mechanically and maybe electrically the tip element 51 to the target beam 49. By repeating this procedure, tip elements 51 and 52 are attached to each of two beams 49 and 50, so that the free ends (not attached to the target area) now form a gap of the target nano-manipulator. The convergence of the two tip elements 51 and 52 is achieved either by pure translation of the nano-manipulator 1 in relation to the target beams by picking up tip elements that already has the correct angles to provide convergent manipulator means, or by rotating and/or tilting the nanomanipulator 1 holding the tip elements in relation to the target beams. The movement can be obtained by moving the nano-manipulator 1 holding the tip element, or by moving the target beams, using e.g. a translation stage with the required resolution. The gap size and the shape of the manipulator means may be tuned or adjusted using the method described in relation to FIG. 7A.

According to the method of the fifth aspect a nano-manipulator can be fabricated in still another way. The nano-manipulator beams 49 without manipulator means is moved close to a tip element 51, that could be but does not have to be free-standing on a surface as illustrated in FIG. 11A. By proper rotation and tilting of the tip element, or alternatively rotation and tilt of the nano-manipulator, one of the target beams is brought within 100 nm of a free end of the tip elements. The elongated object is then attached to the target beam using a focused particle beam as described previously. As illustrated in FIG. 11B, by proper rotation and tilting of the tip elements or the target beams, the procedure can be repeated so that a tip element is attached to each of the target beams, forming a new nano-manipulator. Again, the gap size and the shape of the manipulator means may be tuned or adjusted using the method described in relation to FIG. 7A.

1. A nano-manipulator comprising
a first and a second beam anchored to a support in at least one point,
first and second manipulator means held by the first and second beam respectively, said manipulator means being formed by induced growth with a focused particle beam,
the first and/or the second beam being flexible between at least a first and a second relative position, wherein a distance between the first and second manipulator means in the first and the second position are different, and
means for applying an actuation force to the first and/or the second beam for moving the first and/or the second beam between the first and the second position.

2. A nano-manipulator according to claim 1 wherein the means for applying an actuation force are adapted to apply an electrostatic force to the first and second beams.

3. A nano-manipulator according to claim 1, wherein the means for applying an actuation force comprises
a plurality of actuator beams anchored to the support in at least one point, the plurality of actuator beams being adapted to apply an actuation force to the first and second beams, and
a control circuit for controlling actuation forces applied by the plurality of actuator beams to the first and second beams.

4. A nano-manipulator according to claim 3, wherein the actuation beams are adapted to apply a force to the first and second beams, the force being chosen from the group comprising electrostatic forces, piezoeresistive forces, piezoelectric forces, ferroelectric forces, ferromagnetic forces, thermoelectric forces, electromagnetic forces, etc.

5. A nano-manipulator according to claim 1, wherein the manipulator means comprises carbon-containing material.

6. A nano-manipulator according to claim 1, wherein the manipulator means is designed in any appropriate form.

7. A nano-manipulator according to claim 6, wherein the manipulator means are adapted to grab objects having a cross-section between 1 nm and 10 μm.

8. A nano-manipulator according to claim 1, wherein the manipulator means are elongated tip element(s) having predetermined length(s) between 100 nm and 100 μm.

9. A nano-manipulator according to claim 8, wherein the elongated tip element define a diameter, the diameter being between 10 nm and 10 μm.

10. A nano-manipulator according to claim 8, wherein the free end of the elongated tip element has a radius of curvature between 1 nm and 10 μm.

11. A nano-manipulator according to claim 1, wherein the manipulator means are adapted to grab objects of any form, such as a form chosen from the group comprising spherical, elliptical, cubic, rectangular, triangular, polyhedral, amorphous, etc.

12. A nano-manipulator according to claim 1,,wherein the distance between the first and the second manipulator means is between 1 nm and 20 μm.

13. A nano-manipulator according to claim 3, wherein at least one of the actuation beams is positioned between the first and second beams.

14. A nano-manipulator according to claim 13, wherein actuation forces applied by the at least one actuation beam positioned between the first and second beams decrease the distance between the first and second manipulator means.

15. A nano-manipulator according to claim 1, further comprising a control circuit having electrical connections to the manipulator means, the control circuit being adapted to control electrical measurements being performed by the manipulator means.

16. A nano-manipulator according to claim 1, further comprising positioning means for positioning the manipulator in three dimensions, with respect to a surface or an object to be manipulated.

17. A nano-manipulator according to claim 1, further comprising interface means for controlling the operation of the nano-manipulator.

18. A nano-manipulator according to claim 17, wherein the interface means comprises means chosen from the group comprising keyboards, computer mouse, joysticks, track pads, datagloves, computer input devices, digitisers, digitiser pens, etc.

19. A method of manipulating an object using a nano-manipulator according to claim 1

20. A method for fabricating a nano-manipulator, the method comprising the steps of:
providing a support,
forming a first and a second beam anchored to the support in at least one point,
placing the first and second beams at low pressure and in the presence of materials to be grown,
forming a first manipulator means by directing a focused particle beam to the first beam to induce growth of the first manipulator means and controlling the thickness, length, and shape of the first manipulator means by controlling one or more predetermined parameters of the particle beam and/or beam moving the particle beam focus in relation to the first beam in a predetermined way,
forming a second manipulator means by directing a focused particle beam to the second beam to induce growth of the second manipulator means and controlling the thickness, length, and shape of the second manipulator means by controlling one or more predetermined parameters of the particle beam and/or moving the particle beam focus in relation to the second beam in a predetermined way,
wherein the materials to be grown at least partly determine the material composition of the first and second manipulator means, wherein the first and/or the second beam are/is flexible between at least a first and a second relative position, and wherein a distance between the first and second manipulator means in the first and the second position are different, and
providing means, held by the nano-manipulator, for moving the first and/or the second beam between at least the first and the second position.

21. A method for fabrication according to claim 20, wherein the means for moving the first and/or the second beam comprises means for applying an actuation force to the first and/or the second beam for moving the first and/or the second beam between the first and the second position.

22. A method for fabrication according to claim 21, wherein actuation force are chosen from the group comprising electrostatic forces, piezoeresistive forces, piezoelectric forces, ferroelectric forces, ferromagnetic forces, thermoelectric forces, electromagnetic forces, etc.

23. A method for performing pick & place operations with nanoscale objects, the method comprising the steps of
providing a member and a nanoscale object to be attached to the member,
providing a nano-manipulator adapted to grip and hold nanoscale objects, the nanomanipulator being movable in relation to the member,
gripping and holding the object with the nano-manipulator,
positioning the object close to or in contact with the member by moving the nanomanipulator holding the nanoscale object,
attaching the object to the member, and
releasing the nano-manipulator's grip on the object.

24. A method for performing pick & place operations according to claim 23, wherein the step of attaching the object to the member comprises the step of inducing material growth joining the object and the member by directing a focused particle beam to a region on the member/object and moving the particle beam focus towards the object/member to join the member and the object together by the grown material.

25. A method for performing pick & place operations according to claim 23 wherein the nano-manipulator is a nano-manipulator according to claim 1.

26. A method for performing pick & place operations according to claim 23, wherein the nano-manipulator is a nano-manipulator fabricated according claim 20.

27. A method for performing pick & place operations according to claim 23, wherein the nanoscale object is a carbon nanotube, a silicon nanowire or any type of semiconducting nanowires, metallic nanowires, or insulating nanowires.

28. A method for performing pick & place operations according to claim 23, wherein the nanoscale object is translated and rotated in relation to the member by holding the nanoscale object with the nano-manipulator and translating and rotating the nanomanipulator in relation to the member.

29. A method for fabricating a second nano-manipulator using a first nano-manipulator, the method comprising the steps of:
providing a support,
forming a first and a second beam anchored to the support in at least one point,
providing a first and a second nanoscale tip element
placing the first and second beams and the first and second tip elements at low pressure and in the presence of materials to be grown,
providing a first nano-manipulator adapted to grip and hold nanoscale objects, the nano-manipulator being movable in relation to the first and second beams,
attaching the first tip element to the first member by
gripping and holding the first tip element with the first nano-manipulator,
positioning the first tip element close to or in contact with the first beam by moving the first nano-manipulator holding the tip element,
inducing material growth joining the first tip element and the first beam by directing a focused particle beam to an anchorage point on the first beam or the first tip element, and
releasing the grip of the first tip element by the first nano-manipulator,
attaching the second tip element to the second member by
gripping and holding the second tip element with the first nano-manipulator,
positioning the second tip element close to or in contact with the second beam by moving the first nano-manipulator holding the tip element,
inducing material growth joining the second tip element and the second beam by directing a focused particle beam to an anchorage point on the second beam or the second tip element, and
releasing the grip of the second tip element by the first nano-manipulator,
wherein the first and/or the second beam are/is flexible between at least a first and a second relative position, and wherein a distance between the first and second tip elements in the first and the second position are different, and
providing means, held by the second nano-manipulator, for moving the first and/or the second beam between at least the first and the second position.

30. A method for fabricating a nano-manipulator according to claim 29, wherein at least one of the tip elements is a carbon nanotube, a silicon nanowire or any type of semiconducting nanowires, metallic nanowires, or insulating nanowires.

31. A method for fabricating a nano-manipulator according to claim 29, wherein the tip elements are formed by induced growth in a controlled atmosphere using a focused particle beam.

32. A method for fabrication according to claim 29, wherein the means for moving the first and/or the second beam comprises means for applying an actuation force to the first and/or the second beam for moving the first and/or the second beam between the first and the second position.

33. A method for fabrication according to claim 32, wherein actuation force are chosen from the group comprising electrostatic forces, piezoeresistive forces, piezoelectric forces, ferroelectric forces, ferromagnetic forces, thermoelectric forces, electromagnetic forces, etc.

34. A method for fabrication according to claim 29, wherein the first nano-manipulator is a nano-manipulator according to claim 1.

35. A method for fabrication according to claim 29, wherein the step of inducing material growth joining a tip element and a beam comprises moving the particle beam focus from the beam/tip element towards the tip element/beam to join the beam and the tip element together by the grown material.

36. A method for fabricating a nano-manipulator, the method comprising the steps of:
providing a support,
forming a first and a second beam anchored to the support in at least one point,
providing a first and a second nanoscale tip element
placing the first and second beams and the first and second tip elements at low pressure and in the presence of materials to be grown,
positioning the first tip element close to or in contact with the first beam,
inducing material growth joining the first tip element and the first beam by directing a focused particle beam to an anchorage point on the first beam or the first tip element,
positioning the second tip element and the second beam close to, or in contact with, each other,
inducing material growth joining the second tip element and the second beam by directing a focused particle beam to an anchorage point on the second beam or the second tip element,
wherein the first and/or the second beam are/is flexible between at least a first and a second relative position, and wherein a distance between the first and second tip elements in the first and the second position are different, and
providing means, held by the second nano-manipulator, for moving the first and/or the second beam between at least the first and the second position.

37. A method for fabricating a nano-manipulator according to claim 36, wherein at least one of the tip elements is a carbon nanotube, a silicon nanowire or any type of semiconducting nanowires, metallic nanowires, or insulating nanowires.

38. A method for fabricating a nano-manipulator according to claim 36, wherein the tip elements are formed by induced growth in a controlled atmosphere using a focused particle beam.

39. A method for fabrication according to claim 36, wherein the means for moving the first and/or the second beam comprises means for applying an actuation force to the first and/or the second beam for moving the first and/or the second beam between the first and the second position.

40. A method for fabrication according to claim 39, wherein actuation force are chosen from the group comprising electrostatic forces, piezoeresistive forces, piezoelectric forces, ferroelectric forces, ferromagnetic forces, thermoelectric forces, electromagnetic forces, etc.

41. A method for fabrication according to claim 36, wherein the step of inducing material growth joining a tip element and a beam comprises moving the particle beam focus from the beam/tip element towards the tip element/beam to join the beam and the tip element together by the grown material.
